(19) United States
(12) Patent Application Publication
(10) Pub. No.: US 2008/0259976 A1
(43) Pub. Date: Oct. 23, 2008

(54) Organic Columnar Thin Films

(75) Inventors: Peter C.P. Hrudey, Vancouver (CA); Kenneth L. Westra, Edmonton (CA); Michael Julian Brett, Edmonton (CA)

Correspondence Address: CHRISTENSEN, O'CONNOR, JOHNSON, KINDNESS, PLLC, 1420 FIFTH AVENUE, SUITE 2800, SEATTLE, WA, 98101-2347, US

(73) Assignee: THE GOVERNORS OF THE UNIVERSITY OF ALBERTA, Edmonton, AB (CA)

(21) Appl. No.: 12/095,119

(22) PCT Filed: Nov. 30, 2006
(86) PCT No.: PCT/CA06/01964

§ 371 Date: May 27, 2008

Related U.S. Application Data
(60) Provisional application No. 60/740,901, filed on Nov. 30, 2005.

(51) Int. Cl. H01S 3/10; H01L 33/00; G02F 1/03; B32B 5/00; C23C 16/00; B05D 5/06

(52) U.S. Cl. 372/27; 359/252; 257/98; 438/29; 428/221; 428/222; 427/255.6; 427/166; 257/E33.067

(57) ABSTRACT

A thin film includes a substrate and a transparent, porous film of organic material, such as 8-hydroxyquinoline aluminum. The organic material is vapor deposited on the substrate such that the film has distinct helical columns extending away from the substrate.

### BACKGROUND

Nanostructured materials such as nanoparticles and nanowires have been the focus of many research studies. For many practical applications, it is desirable to exert control over the orientational order of the nanostructures. The glancing angle deposition (GLAD) process, as described in U.S. Pat. Nos. 5,866,204 and 6,206,065, has been used to produce various inorganic thin film structures.

### SUMMARY

In one embodiment, there is provided an organic thin film with distinct columns formed by depositing organic vapour depositable material on a substrate. In another embodiment, there is provided a film of organic material vapor deposited on a substrate, the organic material forming distinct columns directly on the substrate. In another embodiment, a method is provided of making an organic thin film of vapor deposited material extending in distinct columns from a substrate. In another embodiment, a method is provided of surface modifying a substrate prior to exposing the substrate to a vapor flux of organic material such that distinct columns are formed directly on the substrate. In various embodiments, the structure of the columns may be varied by control of the depositional process, and for example the columns may be porous and helical. In some embodiments, the distinct columns have a microstructure that produces optical effects in wavelengths of light visible to a human eye. In some embodiments, the distinct columns are vapor deposited directly on the substrate, and the substrate may be surface modified prior to deposition.

In some embodiments, organic material such as 8-hydroxyquinoline aluminum (AlQ3) is vapor deposited in distinct helical columns, as for example with a technique called glancing angle deposition (GLAD). Chiral films made of AlQ3 emit circularly polarized light under electrical excitation or photoexcitation and consist of highly uniform, self-organized arrays of sub-micrometer helices.

Organic thin films made of vapor deposited material extending in distinct columns from a substrate enable the combination of the molecular diversity offered by organic chemicals and the complex sub-micrometer morphologies achievable by GLAD in a single-step process.

These and other embodiments of the device and method are set out in the claims, which are incorporated here by reference.

### BRIEF DESCRIPTION OF THE FIGURES

Embodiments will now be described with reference to the figures, in which like reference characters denote like elements, by way of example, and in which:

FIG. 1 is a detailed perspective view of an organic chiral thin film;

FIG. 2 is a schematic showing an apparatus for making organic thin films, with the substrate shown in side view;

FIG. 3 is a schematic showing an apparatus for making organic thin films, with the substrate shown in top view;

FIG. 4 shows the control components for the apparatus of FIGS. 3 and 4;

FIG. 5 shows an organic thin film with helical structures extending from a substrate;

FIG. 6 shows an organic thin film with helical structures, a cap and electrodes;

FIG. 7 shows an organic thin film in an anti-glare application;

FIG. 8 is a detailed side elevation view of a thin film having a square spiral morphology.

FIG. 9 is a detailed side elevation view of a thin film having an S-shape morphology.

FIG. 10 is a detailed side elevation view of a thin film having a zig-zag morphology.

FIG. 11 is a detailed perspective view of an organic chiral thin film without a wetting layer.

FIG. 12A is a graph comparing the transmission spectra for different thin films;

FIG. 12B is a graph comparing the photoluminescence spectra for left-circularly polarized (LCP) and right-circularly polarized (RCP) light; and

FIG. 12C is a graph comparing the dissymetry factor for different thin films.

### DETAILED DESCRIPTION

A thin film is provided that is formed by vapor depositing organic material in distinct columns on a substrate. Columns are formed by arranging the vapor flux to arrive at an angle to a normal of the substrate. Variation of the flux arrival angle, for example by movement of the substrate or movement of the vapor source, causes different columnar structures to be formed.

In one embodiment, the fabrication of a luminescent organic thin film may be achieved using a robust, single-step deposition process called glancing angle deposition (GLAD). An organic thin film made by the GLAD technique may be characterized by having a highly uniform, self-organized array of sub-micrometer scale structures. When the microstructures are helical, the films generate circularly polarized luminescence as a result of the chiral morphology of the nanostructures and the luminescent properties of the organic material. Thus in one embodiment, the thin film may be organic, porous and chiral, with a microstructure engineered on the scale of optical wavelengths.

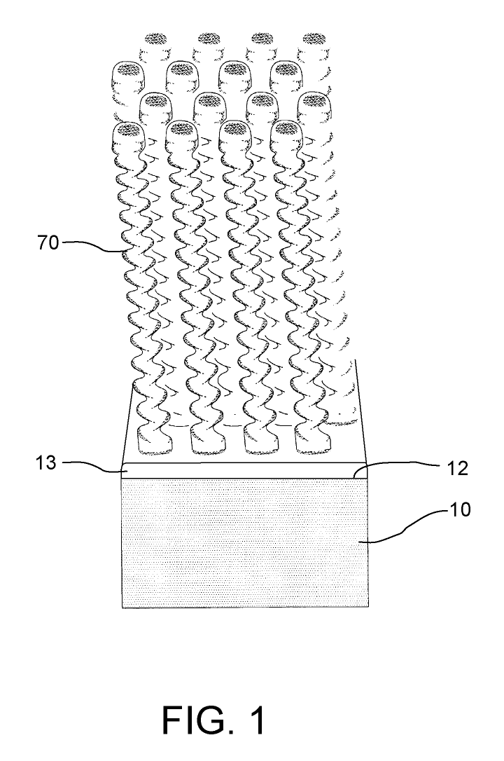

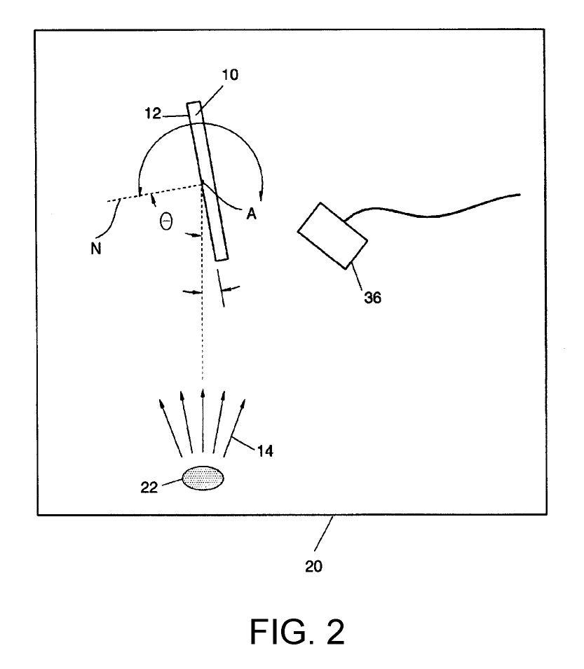

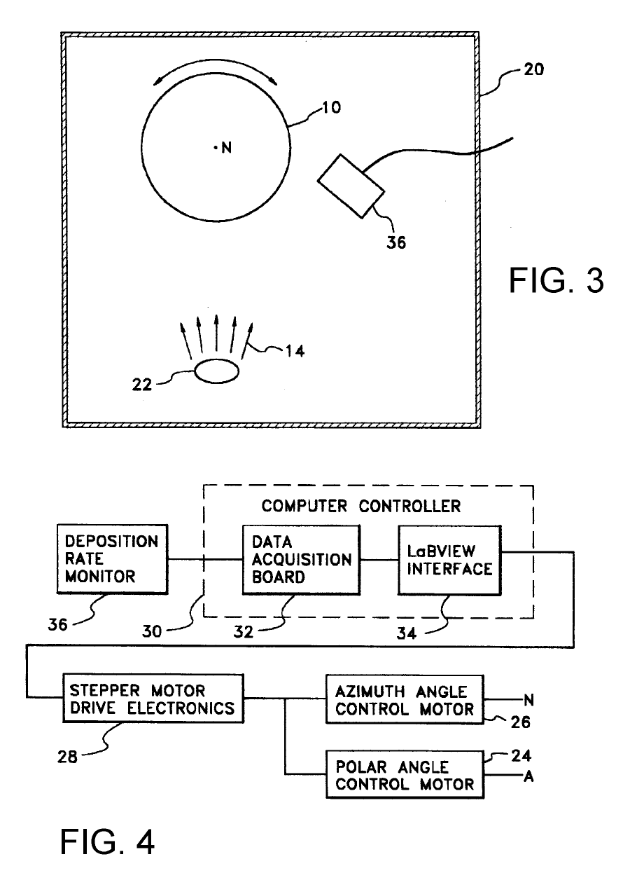

Referring now to FIGS. 2, 3 and 4, an apparatus is described for carrying out the GLAD process for growing a thin film 70 on a substrate 10 having a surface 12, as shown in FIG. 1. This discussion is taken from U.S. Pat. Nos. 5,866,204 and 6,206,065. The substrate may be any solid material on which a vapor may be deposited, and will depend on the application. Silicon substrates will be commonly used. The material to be deposited may be any organic material for which conditions are achievable to support vapor generation and deposition of the vaporized material on the substrate. In some cases, this may require cooling or heating of the substrate. To assist in bonding one vaporized material to another, an intervening layer may be first deposited. The processes described here should be carried out in conditions in which the vapor flux arrives at the substrate in approximately a straight line. For this reason, it is preferred that the process be carried out under conditions approximating a vacuum, at less than 10⁻³ torr, for example at 10⁻⁶ torr. At higher pressures, scattering from gas molecules tends to prevent well defined structures from growing. In addition, the material used should have a sufficiently high sticking co-efficient, such as at least about 0.9 to enable the formation of distinct structures.

The organic material that forms the thin film 70 made of nanostructured columns may be any organic material capable of being vapour deposited on a substrate. For example, those used for organic light emitting diodes (OLED), organic solar cells, and organic thin film transistors (OTFT) may be used. These include, but are not limited to, organic semiconductors used as charge transport layers (i.e. hole injection layers, hole transport layers, hole blocking layers, and electron transport layers), dye sensitizers, absorbers, and emission layers. Organic materials that may be vacuum or vapour deposited include coordination complexes, some organo-metallic complexes and some fatty acids. Based on the successful fabrication of porous nanostructured thin films from AlQ3 and TPD, it is believed on reasonable grounds that, in particular, the following groups of organic materials will form nanostructured growths upon vapor deposition using the GLAD process:

quinoline salts (e.g. Alq3, Znq3, Gaq3)

phthalocyanine salts (e.g. CuPc)

acenes or polyacenes (e.g. pentacene)

benzidines (including TPD and NPD)

thiophenes (e.g. quarterthiophene)

oxadiazoles

porphines

quinacridones

thiazolines

triazoles

triphenylamines

oligomers

Larger molecules such as organic polymers or biological organics may have some difficulty with vapour deposition that produces microstructures with optical effects. In such cases, it may be possible to functionalize the organics to make them vapour depositable, or to vapor deposit the constituent monomers and attempt to react the molecules at the substrate to form the desired polymers.

The angle of incidence of the incoming vapour to the substrate normal should be high enough to allow atomic shadowing to create distinct columns. Angles greater than 70 degrees have been found suitable. The rate of rotation may be varied to change the pitch, which may for example be 200 to 500 nm. Up to 40 turns or more may be achieved in a single helix. The optical character of helical columnar thin films disclosed here depends on the pitch of the helix and the cross-sectional diameter of the thread or wire forming the helix. The precise pitch needed for optical effects depends on the index of refraction of the medium surrounding the thin film, but will generally be sub-micron, and most often sub-500 nm for optical applications at visible wavelengths when the medium is air. These pitches are possible because the cross-sectional diameter of the thread achieved using the principles discussed herein is typically sub-200 nm or sub-100 nm. This aspect may also be used to produce other useful microstructures of interest, such as helices having a larger pitch. Non-helical microstructures can also benefit from having such dimensions, because this can allow the film designer to produce films with increased porosity and high surface area. High surface area is useful in optical applications of columnar thin films infiltrated by another medium (e.g. liquid crystals or a dye solution). In general, microstructures having a size in the range of wavelengths of visible light, for example below 700 nm, will have optical effects. The main consideration to produce optical effects is that the optical size (i.e. the index of refraction times the size) of the microstructures of the columns correspond to visible wavelengths. With an index of refraction greater than 1, the size of the microstructures will typically be smaller than 700 nm for applications at visible wavelengths.

A vapor source 22 of organic material is located within a vacuum chamber 20. A conventional shutter (not shown) located above the vapor source 22 is used to control whether or not the substrate 10 is exposed to vapor. Various conventional means (not shown separately) for causing the vapor source 22 to emit a vapor flux 14 may be used. A substrate 10 is supported in the vacuum chamber 20 on a motor 24 (FIG. 4) disposed in the vacuum chamber 20 above the vapor source 22. The motor 24 rotates the substrate about an axis A lying parallel to and preferably in the plane defined by the surface 12 of the substrate 10. Rotation of the substrate 10 about axis A alters the polar angle, namely the angle of incidence θ of the vapor flux 14. Motor 26, also disposed in the vacuum chamber 20 above the vapor source 22, has a rotational axis coinciding with the normal N of the substrate 10 and thus alters the azimuthal angle. The polar angle and the azimuthal angles are both measures of the orientation of the surface of the substrate to the incident flux. Various mounting arrangements of motor 24 and motor 26 may be used. Referring now to FIG. 4, motors 24 and 26 are preferably conventional stepper motors driven by stepper motor drive electronics 28 and controlled by computer controller 30. The computer controller 30 includes a data acquisition board 32 and a software based interface 34 such as LabVIEW™ available from National Instruments. The data acquisition board 32 receives signals indicative of thin film growth on the substrate output from a deposition rate monitor 36 of conventional construction located within the vacuum chamber 20 in a location in which film growth on the deposition rate monitor 36 is representative of film growth on the substrate 10. In response to receiving the output signals from the deposition rate monitor 36, the computer controller 30 instructs the driver 28 to cause the motors 24 and 26 to rotate according to a desired pattern. As described herein, the computer automatically controls the rate of change of the orientation of the surface in response to the output control signals to grow the thin film according to the desired pattern. Start and stop signals for vapor deposition may be sent by the computer to a drive for the shutter for starting vapor deposition, or the shutter may be opened manually. Normally, the motors are started before the shutter opens to initiate deposition.

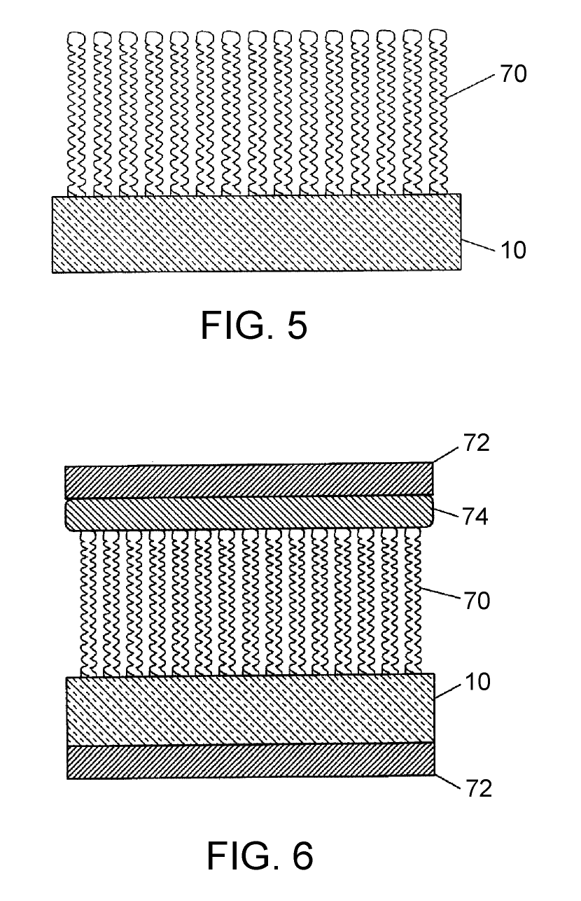

FIG. 4 illustrates a thin film microstructure produced by the process described here with rotation of the substrate about a normal to the substrate. Vapor deposited material extends in distinct (separate from one another) helical columns 70 from the substrate 10. FIG. 5 illustrates the same thin film with the distinct helical columns 70 terminating distally from the substrate 10 in a region of denser material forming a cap 74 for the helical columns. The cap 74 may be produced by changing the angle of incidence of the flux from θ near 90 degrees to zero (corresponding to rotation about an axis parallel to the substrate surface), or the deposition of the helical columns may be ended under conditions giving rise to a higher diffusion length, as for example higher substrate temperature or changing to a lower melting point material.

Applications for the sculpted thin film helical growths described here include uses as helicoidal bianisotropic media, which are useful in a wide range of applications, as for example as isolators, circular polarizers, quarter-wave and half-wave plates, frequency converters and notch filters. When used as helicoidal bianositropic media, the vapor deposited material should be at least partially transparent at the wavelength of the electromagnetic radiation of interest. The helical growths 70, illustrated in FIG. 5, deposited on a substrate 10, and grown with rotation of the substrate about a normal to the surface of the substrate, (with or without capping) may be sandwiched between two transparent charged electrodes 72 as shown in FIG. 6. The electrodes 72 are shown schematically and in practice may be thicker. The electrodes 72 may be made from indium tin oxide or other transparent electrically conducting material and preferably take the form of plates. The cap 74 is preferably made from the same material as the helical growths, but need not be. When used with bounding electrodes such as those shown in FIG. 6, the cap 74 and substrate 10 act as insulators. If insulators are not required in an application, then the substrate 10 may be conducting and the cap may form the upper electrode. The structure shown in FIG. 6 may be used as an optical filter for circularly polarized light. By applying a charge to the electrodes 72, the electrodes 72 may be pulled together or pushed apart and thus change the pitch of the helices 70. This has the effect of tuning the filter created by the thin film. As compared with at least some inorganic helical thin films, the organic AlQ3 helical thin films are softer. For example, calculations show that a 2 μm thick film of AlQ3 should deflect 100 nm. In addition, the AlQ3 helical thin film appears to be capable of taking 30 Volts across the thin film. Such features would make the organic thin film superior as a tunable filter as compared with inorganic helical thin films.

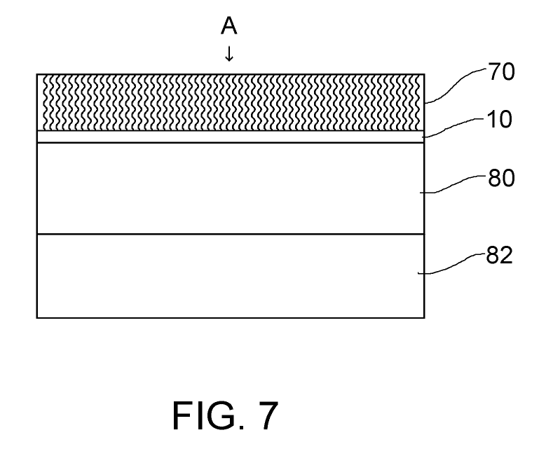

Additional applications for the organic thin films described here include anti-glare LED displays, and circularly polarized lasing devices. In anti-glare LED displays, such as the example shown in FIG. 7, an LED array 80 is provided between a mirror 82 and an organic helical thin film 70 on a transparent substrate 10. Ambient light A entering the organic helical thin film 70 will be circularly polarized, pass through the LED array 80, reflect off the mirror 82, which reverses the polarity of the polarization, then pass through the LED array 80 again and then be largely blocked by the circular polarization of the organic helical thin film 70. The degree of blocking or filtering of the ambient light depends on the percentage of single handedness of the circularly polarized light. In the case of organic helical thin films, the percentage of single handedness can reach in excess of 90%, which would result in considerable anti-glare effect.

In a circularly polarized laser, an organic helical thin film is doped with a suitable lasing material. The pitch of the organic helical thin film is selected to provide low transmittivity for a single handedness of circularly polarized light in a band defined by upper and lower cut-off frequencies. The doping material is selected to have laser emission in the same band, preferably centered in the center of the band. Upon excitation of the doped material, such as for example by a second laser, the organic helical thin film will emit circularly polarized laser light at the upper and lower cut-off frequencies.

Devices may also be made that include different materials within a single column of vapour deposited material. Thus, a column made by oscillating the deposition angle during deposition, as if making a capping layer as described in U.S. Pat. No. 5,866,204, may include both organic and inorganic materials. For example, titanium oxide may be vapour deposited for a first time period, followed by AlQ3, then followed by a further deposition of titanium oxide. Such structures may be used to tailor a filter, for example by providing a central peak of transmissivity within an absorption band.

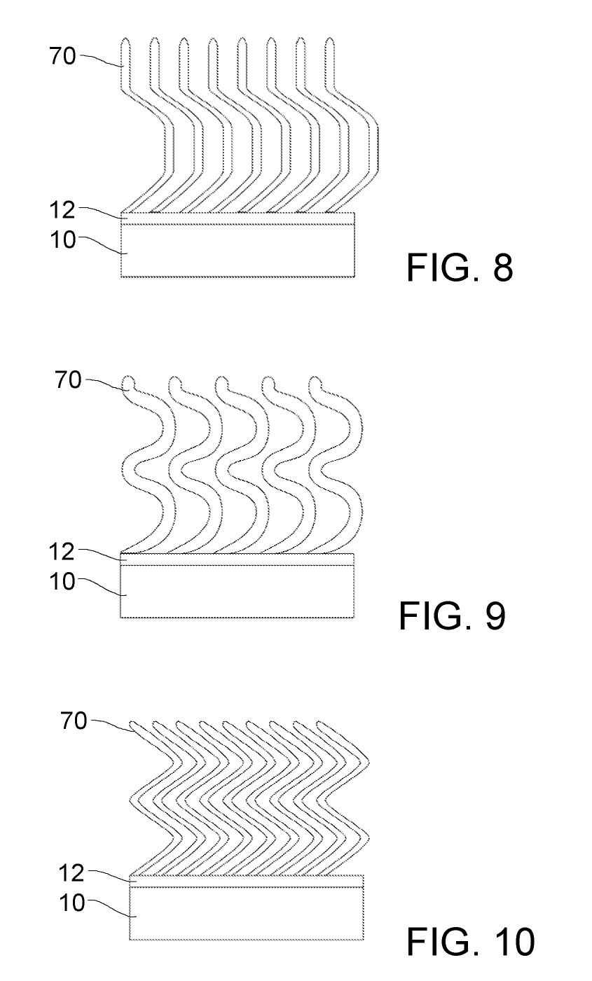

An example will now be described that includes a one-step fabrication of an organic porous chiral thin film with engineered sub-micrometer structure. In one embodiment, the organic material may be the organic light emitting diode (OLED) material AlQ3, which may be used to produce polarized light emitting thin films. The fabrication process, GLAD, utilizes deposition onto rotating substrates which are computer-controlled to accurately and actively vary the incident flux angle and substrate rotation speed during the deposition. In addition to the example given, numerous film morphologies can be fabricated using GLAD techniques, including tilted columnar, vertical columnar, helical, s-shapes, zig-zags, polygonal spiral, and gradient density columnar. Referring to FIG. 8 through 10, square spiral (linear in the side view shown, having a square shape viewing from the top), s-shape and zig-zag morphologies are shown, respectively, as examples of the possible morphologies

The circular Bragg effects exhibited by porous chiral thin films are typified by an optical stop band that reflects one handedness of circularly polarized light between λ₁=pnₒ and λ₂=pnₑ, where nₒ and nₑ are the ordinary and extraordinary indices of refraction of the chiral structure, and p is the helical pitch.

The organic luminescent porous chiral films described below were evaporated from 8-hydroxyquinoline aluminum (AlQ3) source material at deposition angle of 85° (the angle between the incoming vapour direction and the substrate normal). A dense reference film of AlQ3 was deposited at normal incidence to confirm that any polarization effects observed were a consequence of the morphology of the porous chiral films. All films were deposited on both (100) silicon substrates and 7059 glass substrates that were used as-supplied. Thus, a native oxide was expected to be present upon the silicon substrates. The morphologies and structures are represented by FIG. 1

Examples of films produced using the steps described herein, and which were used in the analysis below, include films that are right-handed helical films with 5.5 turns at a pitch of 414 nm (˜2.275 μm total thickness) and 9.25 turns at a pitch of 370 nm (˜3.420 μm total thickness), with densities of ˜63% of the solid reference film, as measured using a quartz microbalance. These values can be used to predict the spectral location of the maximum circular Bragg effect because it should occur at λ=pn_{avg}, where n_{avg} is the average index of refraction obtained using the density-weighted sum of the AlQ3 and the voids between the AlQ3 helices. Using an index of 1.7 for AlQ3 and an index of 1 for the voids, the maximum circular Bragg effect should occur at ˜595 nm and ˜533 nm for the 5.5 and 9.25 turn films, respectively. Film thickness measurements of samples at the edges and at the center of the chuck were taken to determine the film thickness uniformity, which was 97%.

The organic porous chiral films that were produced demonstrated a high level of self-organization and a uniform nature. Compared with inorganic GLAD films, these organic films displayed substantially less bifurcation and no broadening of the columnar structure. For example, the individual helices were ˜75 nm in diameter at both the film-substrate interface and the film-surface interface in the above examples. The individual organic helices were also observed to possess remarkably smooth surfaces. Both the samples deposited on silicon and those deposited on glass were imaged with SEM and found to exhibit these smooth, organized, and non-broadening structures. Inorganic chiral films formed using GLAD are subject to various defects, are much more randomly distributed, and often consist of helices with rougher surfaces. Two defects which commonly occur are bifurcation and broadening of the individual helices, which negatively impact the optical performance of GLAD films. No structural dependence on the deposition rate was observed for the chiral AlQ3 films produced, which were deposited at rates of 5-15 Å/s with no substrate heating.

Referring to FIG. 1, the first ˜200 nm of these chiral films is a layer 13, referred to as a wetting layer, that is actually solid and exhibits no chiral morphology. While the exact details of the growth of these structured AlQ3 films remains under investigation, this initial solid layer of the films provides some evidence regarding the nature of the growth of these films. During the initial growth, the AlQ3 wets to the substrate, which is either the native oxide on the silicon wafers or glass for these experiments, as both the substrate and the AlQ3 molecules are polar. Above a certain thickness, the polar AlQ3 molecules begin to dewet from the apolar surface of the initially solid AlQ3 layer, leading to a partial wetting regime. Once growth enters this partial wetting regime, continued growth occurs at the AlQ3 droplets that form on the surface as these droplets receive most of the incoming vapor flux due to its glancing angle of incidence. The nearly hexagonal close-packed (hcp) arrangement of the helical AlQ3 structures observed here could perhaps be understood to occur due to a combination of diffusive interactions between droplets causing their centers of mass to migrate to empty regions on the substrate with the effect of the continuous substrate rotation, which may force the structures to form in an arrangement with a high degree of rotational symmetry, as is the case for the hcp arrangement.

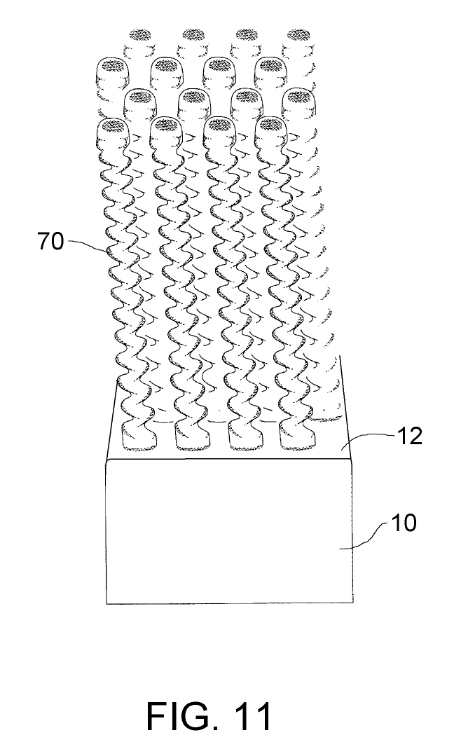

The morphology of nanostructured, porous organic vapor deposited films may be controlled by employing certain techniques. In particular, the deposition rate may be controlled by using a highly temperature stable vapor source, such as a low temperature effusion cell, to allow for precise and stable control over the deposition rate. In addition, the wetting layer may be controlled by adjusting the deposition rate and the deposition angle. As the deposition rate is increased, the thickness of the solid wetting layer formed during the initial growth stages is also decreased, or alternatively, a lower deposition rate increases the thickness of the wetting layer, depending on the desired outcome for a given application. As the deposition angle is increased from the normal of the substrate, the thickness of the solid wetting layer formed during the initial growth stages is reduced, whereas a lower deposition angle increases its thickness. Alternatively, surface treatments or surface modification may be used to control or prevent the formation of the wetting layer altogether as shown in FIG. 11. For example, by making the surface of the substrate hydrophobic (or less polar), the formation of the wetting layer is prevented. This may be done by chemically treating the substrate, such as by applying a monolayer of octadecyltrichlorosilane to the substrate. Alternatively, the surface may be seeded, such as seeds made by photolithography using SU-8 or other photoresists, to prevent the formation of the wetting layer and also to create a specific pattern of columns. A further technique involves controlling the substrate temperature, for example by changing the ratio of the substrate temperature to the melting point of the material being deposited.

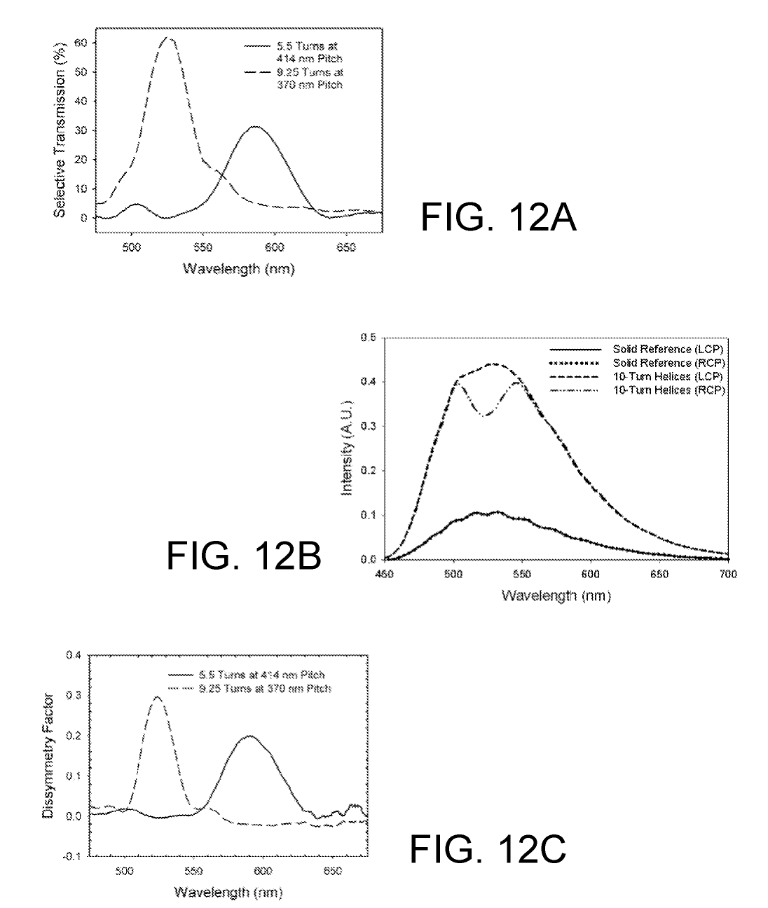

Referring to FIGS. 12A and 12B, the optical properties of embodiments of organic luminescent chiral films were characterized by spectroscopic ellipsometry and circularly polarized photoluminescence measurements. The peak selective transmission of left- versus right-circularly polarized light (normalized to the left-handed transmission to account for diffuse scattering effects) for the 5.5 turn film occurs at ˜587 nm with a selective transmission response of ˜31%, whereas a peak of ˜62% occurs at ˜525 nm for the 9.25 turn film. These peaks correspond well to the values reported above, confirming the predicted circular Bragg effects.

Referring to FIG. 12C, to quantify the observed circularly polarized photoluminescence data, the dissymmetry factor, gₑ

gₑ=2(IL−IR)/(IL+IR) (1)

can be used, where IL and IR are the left- and right-handed emission, respectively. The dissymmetry factor ranges between theoretical limits +2 for completely left-circularly polarized light and −2 for right-circularly polarized light. In practice, gₑ is limited by the isotropic distribution of luminescent centres throughout the thickness of the film. Our preliminary organic luminescent porous chiral films show substantial promise with the 9.25 turn film achieving a peak dissymmetry factor of 0.30 at a wavelength of 524 nm, and the 5.5 turn film achieving peak dissymmetry factor of 0.20 at 590 nm.

The locations of the peak response for both the transmission and the photoluminescence measurements agree indicating that the helical structure of the films is acting as a circular polarization filter or reflector, and that we are able to predictably control the polarization properties of these organic chiral films. Since the pitch and handedness can be actively varied during deposition, gradient pitch or multi-pitch structures can readily be made with desired polarization effects over a wide spectral range, and with circular Bragg effects for both left- and right-circularly polarized light at specific wavelengths. Furthermore, other morphologies can be included in films to provide additional functionality. For example, tilted columnar films exhibit form birefringence and could be used to integrate waveplate structures into a chiral-linear heterostructure.

In summary, chiral thin films of AlQ3 exhibiting diameters under 100 nm and a remarkably high degree of uniformity and ordering were fabricated by low temperature thermal evaporation using the GLAD technique. These structures selectively transmit one handedness of circularly polarized light, and also generate circularly polarized photoluminescence. The single-step deposition of organic films using GLAD provides a means to readily exploit both the engineered morphologies offered by GLAD and the diverse range of organic materials available. This has potential applications in optoelectronics, chemical sensing, and photovoltaics.

### EXPERIMENTAL EXAMPLE

Deposition. 8-hydroxyquinoline aluminum (AlQ3) was sublimated onto (100) silicon (Evergreen Semiconductor Materials) and 7059 glass substrates (Precision Glass and Optics) using a low temperature effusion cell (LTE21000K, Kurt J. Lesker Company). The low temperature effusion cell (LTE21000K, Kurt J. Lesker Company) allows for a very stable control of the source temperature, and thus the deposition rate, during the deposition compared to an electron beam gun or thermal boat source. A jet of dry nitrogen was used to remove any dust from the samples prior to deposition, but otherwise the substrates were used as supplied. The vacuum chamber was at a base pressure <3×10⁻⁵ Torr for all depositions. The substrates were mounted on an unheated substrate chuck attached to a stepper motor controlling the rotation angle of the substrate during the deposition. During deposition, the center of the substrate chuck was held 24 cm from the deposition sources, and the substrate chuck was tilted so that the substrate normal was 85° from the incoming vapour direction. A control computer was used to continuously monitor the deposition rate measured by a quartz crystal thickness monitor, and to rotate the substrate accordingly. The rate of substrate rotation, Ω_{sub}, was related to the deposition rate, r, and the pitch of the film, p, as follows: p=r/Ω_{sub}. Deposition rates were in the range of 5-15 Å/s. Samples on both the silicon and glass substrates were cleaved using a diamond scribe prior to SEM imaging.

Transmission Ellipsometry. A variable angle spectroscopic ellipsometer (VASE, J. A. Woollam, Inc.) used in transmission mode was used to measure the transmission of p- and s-polarized light through the samples deposited on glass, and also to measure the transmission Mueller matrix of these samples, with the m11 coefficient normalized to 1 at all wavelengths. Scans were performed of a wavelength range of 400 nm-700 nm. The transmission of p- and s-polarized light was averaged to determine the un-normalized m11(λ) element of the Mueller matrix, which was used in combination with the m14(λ) element to determine the selective transmission for the samples.

Photoluminescence Detection. The photoluminescent response of the films was measured using the 365 nm emission line of a mercury lamp (Hamamatsu LightningCure L8333) for excitation and a spectrometer (Ocean Optics USB2000) for detection. The excitation light was focused onto a 5 mm by 5 mm square region. The polarization emitted for the helical films was measured by placing a quarter waveplate and a Glan-Taylor polarizer between the sample and the spectrometer for the helical films, with the waveplate fast axis oriented at ±45° to the polarizing axis. The orientation of the polarizer was kept constant with respect to the spectrometer grating, in order to eliminate the polarization sensitivity of the detector. The dense reference film was also tested in this setup and showed identical photoluminescence spectra, and thus a null dissymmetry factor spectrum, for both left- and right-handed emission.

Immaterial variations may be made to the embodiments described here without departing from what is covered by the following claims.

1. A thin film, comprising:
a substrate; and
a film of organic material vapor deposited on the substrate, the film having distinct columns extending away from the substrate, the distinct columns having a microstructure that produces optical effects in wavelengths of light visible to a human eye.

2. The thin film of claim 1, wherein the organic material comprises 8-hydroxyquinoline aluminum.

3. The thin film of claim 1, wherein the columns are helical.

4. The thin film of claim 3, wherein the film emits circularly polarized light under electrical excitation or photoexcitation.

5. The thin film of claim 4, wherein the film selectively emits one handedness of circularly polarized light under electrical excitation or photoexcitation.

6. The thin film of claim 1, wherein the distinct columns comprise one or more of tilted columns, vertical columns, s-shapes, zig-zags, polygonal spiral columns, and gradient density columns.

7. The thin film of claim 1, wherein the substrate comprises glass or silicon.

8. The thin film of claim 1, wherein the organic material comprises one or more organic compounds selected from the following groups of organic compounds: quinoline salts, phthalocyanine salts, acenes or polyacenes, benzidines, thiophenes, oxadiazoles, porphines, quinacridones, thiazolines, triazoles, triphenylamines, and oligomers.

9. The thin film of claim 1, wherein the film is formed by vapor deposition, the vapor being deposited by a vapor flux arriving at the substrate at an angle greater than 70 degrees from a normal to the substrate.

10. The thin film of claim 3, wherein each of the distinct helical columns has a pitch of less than 1 micron.

11. The thin film of claim 10 in which each of the distinct helical columns has a pitch of between 200 nm and 500 nm.

12. The thin film of claim 3, wherein each of the distinct helical columns is formed from a thread having a cross-sectional diameter of less than 200 nm.

13. The thin film of claim 1, wherein the film comprises multiple layers.

14. The thin film of claim 13, wherein at least one layer of the multiple layers has a structure that is one of solid, tilted columnar, vertical columnar, helical, polygonal spiral, gradient density columnar, and capping.

15. The thin film of claim 13, wherein at least one layer is made from inorganic material.

16. The thin film of claim 3, the film having a helical columnar layer and a birefringent layer to form a chiral-linear heterostructure.

17. The thin film of claim 3 for use in a circularly polarized laser, the film being doped with a lasing material.

18. The thin film of claim 3, wherein the film is bianisotropic.

19. The thin film of claim 18, in combination with electrodes for applying a charge across the film to change the pitch of the helical columns, the thin film acting as a circularly polarized light filter.

20. The thin film of claim 1, in combination with an LED array to form an anti-glare LED, the LED layer being positioned between a mirror surface and the substrate, the substrate being transparent.

21. A method of forming a thin film, the method comprising the step of:
exposing a substrate to a vapor flux of organic material arriving at a flux arrival angle to the substrate to form a film of the organic material extending away from the substrate in distinct columns, the distinct columns having a microstructure that produces optical effects in wavelengths of light visible to a human eye.

22. The method of claim 21, wherein the organic material deposited comprises 8-hydroxyquinoline aluminum.

23. The method of claim 21, wherein the distinct columns are helical.

24. The method of claim 23, further comprising the step of electrically exciting or photoexciting the film such that the film emits circularly polarized light.

25. The method of claim 24, wherein the film selectively emits one handedness of circularly polarized light.

26. The method of claim 21, wherein the organic material deposited comprises one or more organic compounds selected from the following groups of organic compounds: quinoline salts, phthalocyanine salts, acenes or polyacenes, benzidines, thiophenes, oxadiazoles, porphines, quinacridones, thiazolines, triazoles, triphenylamines, and oligomers.

27. The method of claim 21, wherein, during vapor deposition, the flux arrival angle is controlled to cause the film to form in one of more of tilted columns, vertical columns, polygonal spiral columns, and gradient density columns.

28. The method of claim 21, wherein each distinct column is formed of a thread having a substantially uniform cross-section.

29. The method of claim 21, wherein the flux arrival angle is greater than 70 degrees from a normal to the substrate.

30. The method of claim 23, wherein each of the helical columns has a pitch between 200 and 500 nm.

31. The method of claim 21, wherein the film is formed by vapor depositing plural layers of distinct columns.

32. The method of claim 31, wherein at least one layer of the plural layers has a structure that is one or more of tilted columnar, vertical columnar, helical, s-shapes, zig-zags, polygonal spiral, gradient density columnar, and a capping layer.

33. The method of claim 32, wherein at least one layer of the plural layers is formed from inorganic material.

34. The method of claim 33, further comprising vapor depositing a birefringent layer on at least one of the substrate and one of the plural layers to form a chiral-linear heterostructure.

35. The method of claim 21 further comprising the step of doping the film with a lasing material.

36. The method of claim 23, further comprising the steps of:
placing the thin film between electrodes; and
applying a charge across the film to change the pitch of the helical columns.

37. The method of claim 21, further comprising the step of placing an LED array between a mirror surface and the substrate, the substrate being transparent to form an anti-glare LED.

38. The method of claim 21, the method comprising depositing a solid layer of organic material between the substrate and the distinct columns.

39. The method of claim 21, further comprising the step of surface modifying the substrate to cause the distinct columns to form directly on the substrate.

40. The method of claim 39, wherein surface modifying the substrate comprises seeding the substrate.

41. The method of claim 39, wherein surface modifying the substrate comprises applying a hydrophobic substance to the substrate.

42. A thin film, comprising:
a substrate;
a film of organic material vapor deposited on the substrate, the organic material forming distinct columns directly on the substrate.

43. The thin film of claim 42, wherein the organic material comprises 8-hydroxyquinoline aluminum.

44. The thin film of claim 42, wherein the distinct columns comprise one or more of tilted columns, vertical columns, s-shapes, zig-zags, polygonal spiral columns, and gradient density columns.

45. The thin film of claim 42, wherein the distinct columns comprise distinct helical columns.

46. The thin film of claim 45, wherein the film emits circularly polarized light under electrical excitation or photoexcitation.

47. The thin film of claim 46, wherein the film selectively emits one handedness of circularly polarized light under electrical excitation or photoexcitation.

48. The thin film of claim 42, wherein the organic material comprises one or more organic compounds selected from the following groups of organic compounds: quinoline salts, phthalocyanine salts, acenes or polyacenes, benzidines, thiophenes, oxadiazoles, porphines, quinacridones, thiazolines, triazoles, triphenylamines, and oligomers.

49. The thin film of claim 45, wherein each of the distinct helical columns has a pitch between 200 and 500 nm.

50. The thin film of claim 45, wherein each thread of the distinct helical columns has a cross-section diameter less than 200 nm.

51. The thin film of claim 42, wherein the film comprises multiple layers.

52. The thin film of claim 51, wherein at least one layer of the multiple layers has a structure that is one of solid, tilted columnar, vertical columnar, helical, s-shapes, zig-zags, polygonal spiral, gradient density columnar, and capping.

53. The thin film of claim 51, wherein at least one layer is made from inorganic material.

54. The thin film of claim 42, the film having a helical columnar layer and a birefringent layer to form a chiral-linear heterostructure.

55. The thin film of claim 45, in combination with electrodes for applying a charge across the film to change the pitch of the helical columns, the thin film acting as a circularly polarized light filter.

56. The thin film of claim 42, in combination with an LED array to form an anti-glare LED, the LED layer being positioned between a mirror surface and the substrate, the substrate being transparent.

57. A method of forming a thin film, the method comprising the step of:
exposing a substrate to a vapor flux of organic material arriving at a flux arrival angle to the substrate to form a film of the organic material extending away from the substrate in distinct columns; and
surface modifying the substrate prior to exposing the substrate to the vapor flux such that the distinct columns are formed directly on the substrate.

58. The method of claim 57, wherein the organic material deposited comprises 8-hydroxyquinoline aluminum.

59. The method of claim 57, wherein, during vapor deposition, the flux arrival angle is controlled to cause the film to form in one of more of tilted columns, vertical columns, s-shapes, zig-zags, polygonal spiral columns, and gradient density columns.

60. The method of claim 57, in which the distinct columns are helical.

61. The method of claim 57, wherein the organic material deposited comprises one or more organic compounds selected from the following groups of organic compounds: quinoline salts, phthalocyanine salts, acenes or polyacenes, benzidines, thiophenes, oxadiazoles, porphines, quinacridones, thiazolines, triazoles, triphenylamines, and oligomers.

62. The method of claim 60, wherein each of the helical columns has a pitch between 200 and 500 nm.

63. The method of claim 57, wherein the film is formed by vapor depositing plural layers of distinct columns.

64. The method of claim 63, wherein at least one layer of the plural layers has a structure that is one or more of tilted columnar, vertical columnar, helical, polygonal spiral, gradient density columnar, and a capping layer.

65. The method of claim 64, wherein at least one layer of the plural layers is formed from inorganic material.

66. The method of claim 57 further comprising the step of doping the film with a lasing material.

67. The method of claim 60, further comprising the steps of:
placing the thin film between electrodes; and
applying a charge across the film to change the pitch of the helical columns.

68. The method of claim 57, further comprising the step of placing an LED array between a mirror surface and the substrate, the substrate being transparent to form an anti-glare LED.

69. The method of claim 57, wherein surface modifying the substrate comprises seeding the substrate.

70. The method of claim 57, wherein surface modifying the substrate comprises applying a hydrophobic substance to the substrate.
